(19) United States
(12) Patent Application Publication
(10) Pub. No.: US 2013/0078577 A1
(43) Pub. Date: Mar. 28, 2013

(54) CHARGED PARTICLE BEAM DRAWING APPARATUS, DRAWING DATA GENERATION METHOD, DRAWING DATA GENERATION PROGRAM STORAGE MEDIUM, AND ARTICLE MANUFACTURING METHOD

(71) Applicant: CANON KABUSHIKI KAISHA, Tokyo (JP)

(72) Inventor: Toru Yamazaki, Utsunomiya-shi (JP)

(73) Assignee: CANON KABUSHIKI KAISHA, Tokyo (JP)

(21) Appl. No.: 13/629,994

(22) Filed: Sep. 28, 2012

(30) Foreign Application Priority Data
Sep. 28, 2011 (JP) 2011-211863

(51) Int. Cl. H01J 3/26; G03F 7/20; G06F 11/00

(52) U.S. Cl. 430/296; 250/396 R; 250/252.1

(57) ABSTRACT

A drawing apparatus of the present invention is an apparatus that performs drawing on a substrate with a plurality of charged particle beams and includes a blanking deflector array including a plurality of blanking deflectors configured to respectively blank the plurality of charged particle beams; and a controller configured to control the blanking deflector array based on drawing data. The controller is configured to control the blanking deflector array such that a position error of the plurality of charged particle beams on the substrate due to a magnetic field generated by the blanking deflector array is less than that in a case where the controller controls the blanking deflector array in accordance with initial drawing data.

### BACKGROUND OF THE INVENTION

1. Field of the Invention

The present invention relates to a drawing apparatus for drawing on a substrate with a plurality of charged particle beams, a drawing data generation method, a storage medium which stores a program for generating drawing data, and an article manufacturing method.

2. Description of the Related Art

In recent years, as micronization of the element, increasingly complex circuit patterns, or a higher capacity of pattern data advance, the drawing accuracy of drawing apparatuses for use in the manufacturing of devices such as semiconductor integrated circuits need to be improved. As a method for realizing such requirements, a drawing apparatus that draws a pattern on a substrate by controlling the deflection and blanking of a charged particle beam such as an electron beam or the like is known. As such a drawing apparatus, Japanese Patent Laid-Open No. 2002-353113 discloses a multiple beam-type charged particle beam exposure apparatus using a plurality of charged particle beams in order to achieve improvements in throughput. The charged particle beam exposure apparatus includes a blanking deflector array (blanker array) in which a plurality of pairs of electrodes for independently deflecting a plurality of charged particle beams is formed into a single flat plate. In addition, M. J. Wieland, “Throughput enhancement technique for MAPPER maskless lithography”, SPIE vol. 7637, 76371Z-1, discloses a drawing apparatus with an increase in the total number of charged particle beams for improving the productivity of a multiple beam-type charged particle beam drawing apparatus. The drawing apparatus includes a blanking deflector array integrated with a pair of electrodes and a C-MOS circuit.

In the multiple beam-type charged particle beam drawing apparatus, it is contemplated that the number of charged particle beams is further increased to realize further improvement in throughput. However, an increase in the number of charged particle beams entails an increase in the scale of the circuit incorporated in the blanking deflector array. Here, since the rate of operation of the circuit incorporated in the blanking deflector array varies with a drawing pattern, the current flowing through the circuit provided in the blanking deflector array may vary with time during drawing processing. A charged particle beam passing through the pair of electrodes provided in the blanking deflector array becomes readily unstable under the influence of the variation of the magnetic field due to a change in current. Thus, an increase in the scale of the circuit may undesirably increase the influence of the variation of the magnetic field on the resolution performance or the superposition accuracy of the drawing apparatus.

### SUMMARY OF THE INVENTION

The present invention provides, for example, a drawing apparatus that is advantageous in decreasing of influence of a magnetic field generated by a blanking deflector array.

According to an aspect of the present invention, a drawing apparatus that performs drawing on a substrate with a plurality of charged particle beams is provided that includes a blanking deflector array including a plurality of blanking deflectors configured to respectively blank the plurality of charged particle beams; and a controller configured to control the blanking deflector array based on drawing data, wherein the controller is configured to control the blanking deflector array such that a position error of the plurality of charged particle beams on the substrate due to a magnetic field generated by the blanking deflector array is less than that in a case where the controller controls the blanking deflector array in accordance with initial drawing data.

Further features of the present invention will become apparent from the following description of exemplary embodiments with reference to the attached drawings.

### BRIEF DESCRIPTION OF THE DRAWINGS

FIG. 1 is a diagram illustrating the configuration of a charged particle beam drawing apparatus according to an embodiment of the present invention.

FIG. 2 is a diagram illustrating the configuration of a blanking deflector array.

FIG. 3 is a flowchart illustrating the flow of internal processing performed in a blanking command generation circuit.

FIGS. 4A and 4B are diagrams illustrating the operation of a blanking deflector array during drawing processing.

### DESCRIPTION OF THE EMBODIMENTS

Hereinafter, preferred embodiments of the present invention will be described with reference to the drawings.

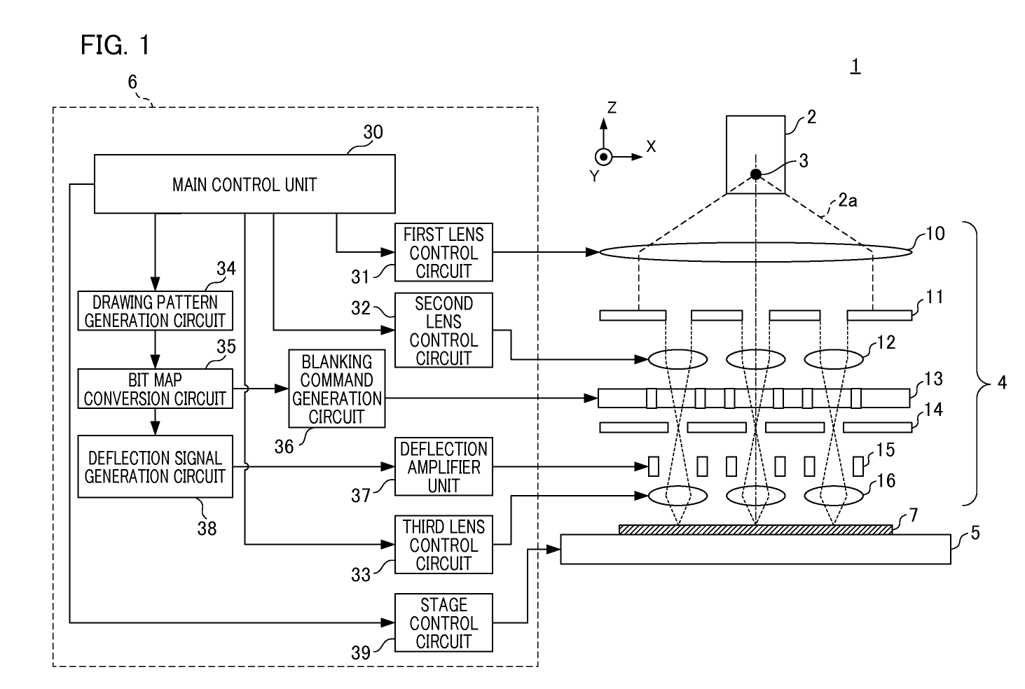

Firstly, a description will be given of a charged particle beam drawing apparatus (hereinafter referred to as “drawing apparatus”) according to one embodiment of the present invention. In particular, the drawing apparatus of the present embodiment is intended to employ a multiple beam system in which a plurality of electron beams (charged particle beams) is deflected and turning the irradiation of electron beams ON and OFF is independently controlled so as to draw predetermined drawing data at a predetermined position on a substrate to be treated (a substrate). Here, a charged particle beam of the present embodiment is not limited to an electron beam, but may be other charged particle beams such as an ion beam. FIG. 1 is a diagram illustrating the configuration of a drawing apparatus according to the present embodiment. In the following drawings, a description will be given in which the Z axis is in an irradiation direction of an electron beam to a substrate to be treated, and the X axis and the Y axis are mutually oriented in directions orthogonal to a plane perpendicular to the Z axis. Furthermore, in the following drawings, the same elements as those shown in FIG. 1 are designated by the same reference numerals. A drawing apparatus 1 includes an electron gun 2, an optical system 4 that splits an electron beam emitted from a crossover 3 of the electron gun 2 into a plurality of electron beams, and deflects and focuses the plurality of electron beams, a substrate stage 5 that holds a substrate to be treated, and a control unit 6 that controls the operation of the components of the drawing apparatus 1. Note that an electron beam is readily attenuated under an atmosphere at normal pressure and is also discharged under high voltage. In order to prevent such a phenomenon, the components except for the control unit 6 are installed in a space of which the internal pressure is appropriately adjusted by a vacuum exhaust system (not shown). For example, the electron gun 2 and the optical system 4 are installed in an electronic optical lens barrel that is held under a high vacuum. Likewise, the substrate stage 5 is installed in a chamber that is held under a relatively lower vacuum than that in the electronic optical lens barrel. Also, a substrate to be treated 7 is a wafer consisting, for example, of single crystal silicon. A photosensitive resist is coated on the surface of the substrate to be treated 7.

The electron gun 2 has a mechanism that emits an electron beam by applying heat or electric field. In FIG. 1, tracks 2a of an electron beam emitted from the crossover 3 are shown by dotted lines. In order from the electron gun 2 to the substrate stage 5, the optical system 4 includes a collimator lens 10, an aperture array 11, a first electrostatic lens array 12, a blanking deflector array 13, a blanking aperture array 14, a deflector array 15, and a second electrostatic lens array 16. The collimator lens 10 is an optical element that is constituted by an electromagnetic lens and collimates an electron beam emitted from the crossover 3 into a collimated beam. The aperture array 11 is a mechanism that has a plurality of circular openings arranged in a matrix form and splits an electron beam incident from the collimator lens 10 into a plurality of electron beams. The first electrostatic lens array 12 is an optical element that is constituted by three electrode plates (in FIG. 1, three electrode plates are shown integrally as an integral plate) each having a circular opening and focuses an electron beam to the blanking aperture array 14. Both of the blanking deflector array 13 and the blanking aperture array 14 are mechanisms that are arranged in a matrix form and perform the ON (non-blanking state)/OFF (blanking state) operation of the irradiation of each electron beam. In particular, the blanking aperture array 14 is arranged at a position at which the first electrostatic lens array 12 first forms the crossover of an electron beam. The deflector array 15 is a mechanism that deflects an image on the surface of the substrate to be treated 7, which is placed on the substrate stage 5, in the X-axis direction. Furthermore, the second electrostatic lens array 16 is an optical element that focuses an electron beam, which has passed through the blanking aperture 14, onto the substrate to be treated 7.

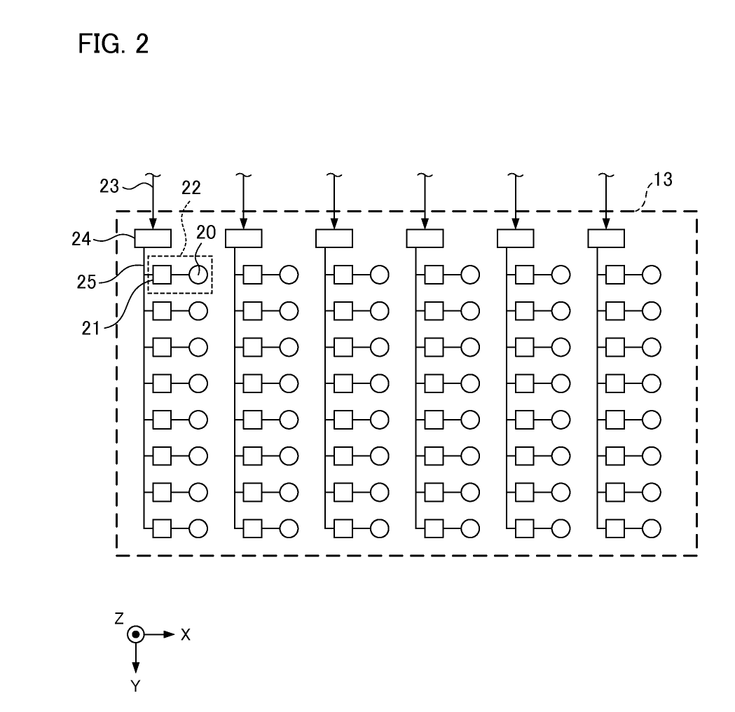

Here, a detailed description will be given of the configuration of the blanking deflector array 13. FIG. 2 is a plan view illustrating the configuration of the blanking deflector array 13. The blanking deflector array 13 is composed of blanking devices (blanking deflector) 22 arranged in an array, where each blanking device 22 includes a pair of electrodes 20 and a drive circuit 21 that controls the blanking operation performed by the pair of electrodes 20. Here, 48 blanking devices 22 are set in array in 6 columns of 8 rows as an example. The pair of electrodes 20 include a driven electrode and an earth electrode (neither shown) so as to face each other at an opening portion through which the electron beam passes after being focused by the first electrostatic lens array 12. The driven electrode is connected to the drive circuit 21 in the same blanking device, whereas the earth electrode is connected to a ground line (not shown) in the blanking deflector array 13. Also, the blanking deflector array 13 includes a plurality of communication processing circuits 24 that receive a command information (a blanking signal), which has been serialized or parallelized, from a blanking command generation circuit 36 to be described below, via a wiring 23 constituted by an optical fiber, an electrical cable, or the like. The communication processing circuit 24 transmits the command information to each drive circuit 21 via a data distribution bus 25. The drive circuit 21 supplies drive current to the pair of electrodes 20 (the driven electrode thereof) based on the command information, and controls the blanking operation of the electron beam by generating an electric field with the pair of electrodes 20. Note that the number of the blanking devices 22 and the arrangement of the blanking devices 22 in the blanking deflector array 13 are not limited to the configuration as described above. The blanking devices 22 may also be arranged in a staggered grid array.

The substrate stage 5 is movable (drivable) at least in the XY axis direction while holding the substrate to be treated 7 using, for example, electrostatic adsorption. The position of the substrate stage 5 is measured in real time by an interferometer (laser length measuring machine) (not shown).

The control unit 6 has various control circuits that control the operation of the components related to drawing with the drawing apparatus 1, and a main control unit 30 that supervises the control circuits. As the control circuits, firstly, a first lens control circuit 31, a second lens control circuit 32, and a third lens control circuit 33 control the operation of the collimator lens 10, the first electrostatic lens array 12, and the second electrostatic lens array 16, respectively. A drawing pattern generation circuit 34 generates a drawing pattern. A bit map conversion circuit 35 converts the drawing pattern into bit map data. A blanking command generation circuit 36 generates the command information based on the bit map data. Here, the control unit 6 includes the blanking command generation circuit 36 and functions as a control unit that controls the blanking deflector array 13. A deflection amplifier unit 37 controls the operation of the deflector array 15 based on a deflection signal generated by a deflection signal generation circuit 38. A stage control circuit 39 calculates a command target value to be input to the substrate stage 5 based on the stage position coordinates which are the command transmitted from the main control unit 30, and drives the substrate stage 5 such that the position of the substrate stage 5 after being driven reaches the target value. During pattern drawing, the stage control circuit 39 continuously scans the substrate to be treated 7 (the substrate stage 5) in the Y-axis direction. At this time, the deflector array 15 deflects an image on the surface of the substrate to be treated 7 in the X-axis direction based on the length measurement result of the substrate stage 5 obtained by an interferometer or the like. Then, the blanking deflector array 13 performs the ON/OFF operation of the irradiation of the electron beam so as to obtain a target dose on the substrate to be treated 7.

Next, a description will be given of the effect of the drawing apparatus 1. If the number of electron beams to be employed is increased so as to achieve improvements in throughput, the scale of the circuit constituting the blanking deflector array 13 also increases. For example, the rate of operation of each of the drive circuits 21 incorporated in the blanking deflector array 13 varies with a drawing pattern, and the current flowing through the circuit provided in the blanking deflector array 13 may vary with time during drawing processing. At this time, an electron beam passing through the opening between each of the pair of electrodes provided in the blanking deflector array 13 is affected by the variation of the magnetic field that has increased due to an increase in the scale of the circuit accompanying an increase in the number of electron beams, resulting in a change in the position of the electron beam. Accordingly, in the drawing apparatus 1 of the present embodiment, the blanking command generation circuit 36 provided in the control unit 6 corrects the drawing pattern (drawing data) output from the bit map conversion circuit 35 so as to reduce the variation.

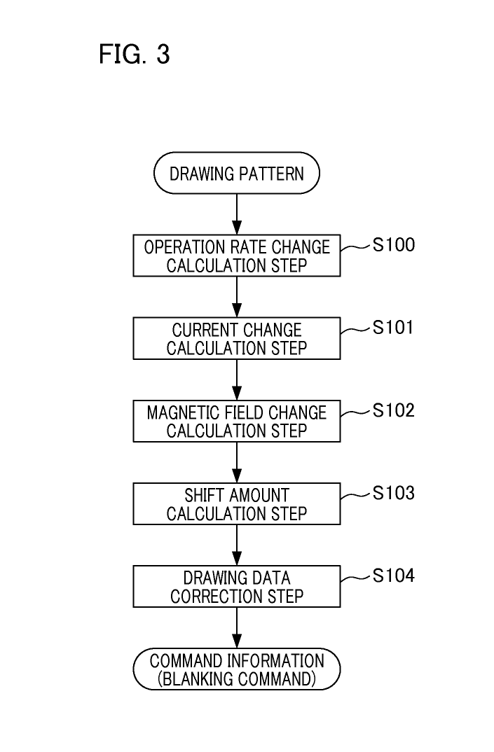

Firstly, a description will be given of internal processing performed by the blanking command generation circuit (command generation unit: hereinafter referred to as “command generation circuit”) 36 according to the present embodiment. FIG. 3 is a flowchart illustrating the flow of internal processing performed by the command generation circuit 36 of the present embodiment. Firstly, the command generation circuit 36 receives the drawing pattern set by the bit map conversion circuit 35, and calculates a change in the rate of operation of the drive circuits 21 in response to the drawing pattern (operation rate change calculation step: step S100). Next, the command generation circuit 36 calculates a change in current flowing through the blanking deflector array 13 based on the change in the rate of operation calculated in step S100 (current change calculation step: step S101). Next, the command generation circuit 36 calculates a change in magnetic field generated by the blanking deflector array 13 based on the change in current calculated in step S101 (magnetic field change calculation step: step S102). Next, the command generation circuit 36 calculates the amount of deflection of an electron beam based on the change in magnetic field calculated in step S102, and further calculates the amount of shift (position error) of the electron beam on the substrate to be treated 7 based on the amount of deflection (shift amount calculation step: step S103). Next, the command generation circuit 36 corrects the drawing pattern based on the amount of shift calculated in step S103 (drawing data correction step: step S104), and transmits command information (blanking command) corresponding thereto to the communication processing circuit 24.

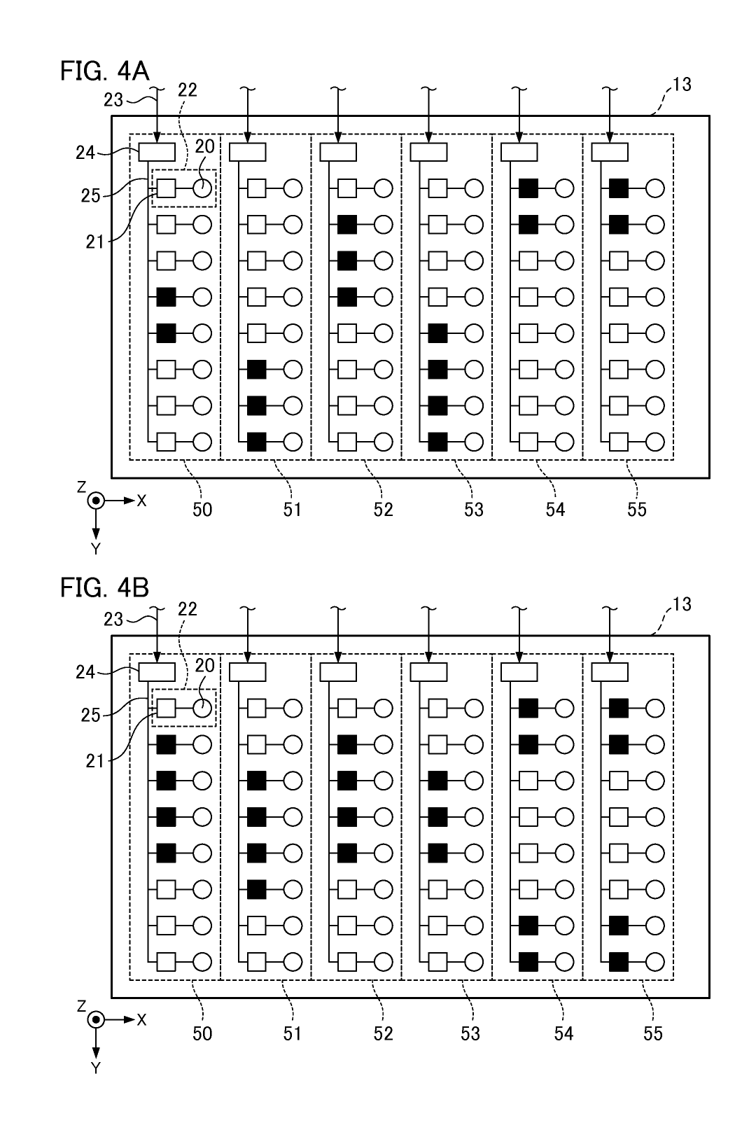

Hereinafter, a detailed description will be given of the calculation steps and the correction step. Firstly, a description will be given of calculation of the change in the rate of operation of the drive circuits 21 in step S100. FIGS. 4A and 4B are diagrams illustrating the state of the blanking deflector array 13 for explaining the change in the rate of operation calculation of the drive circuit 21. The examples in FIGS. 4A and 4B show the case where the blanking devices 22 arranged in array in 6 columns of 8 rows are divided into blocks for each column (6 columns), and the change in the rate of operation of the drive circuits 21 is calculated for each column. Here, the blocks in columns each including eight blanking devices 22 are represented by a first block 50, a second block 51, a third block 52, a fourth block 53, a fifth block 55, and a sixth block 55 for ease of explanation. Here, as shown in FIG. 4A, the operation states of the drive circuits 21 at a certain timing (first timing) during drawing processing based on the initial blanking command are divided into two states: in operation (in blanking operation: open square in FIG. 4A) and not in operation (black square in FIG. 4A). For example, in the first block 50, the number of the drive circuits 21 in operation is six and the number of the drive circuits 21 not in operation is two. In contrast, FIG. 4B is a diagram illustrating the operation state of the drive circuit 21 at the second timing subsequent to the first timing in FIG. 4A. For example, in the first block 50, the number of the drive circuits 21 in operation is changed to four and the number of the drive circuits 21 not in operation is changed to four. Note that the operation states (the number of operation circuits) of the drive circuits 21 for each block are tabulated in Table 1.

TABLE 1

| | THE NUMBER | THE NUMBER |
|---|---|---|
| | OF OPERATION | OF OPERATION |
| | CIRCUITS AT | CIRCUITS AT |
| | FIRST TIMING | SECOND TIMING |
| FIRST BLOCK | 6 | 4 |
| SECOND BLOCK | 5 | 4 |
| THIRD BLOCK | 5 | 4 |
| FOURTH BLOCK | 4 | 5 |
| FIFTH BLOCK | 6 | 4 |
| SIXTH BLOCK | 6 | 4 |

Here, the command generation circuit 36 calculates the difference between the number of operation circuits of the drive circuits 21 at the first timing and the number of operation circuits of the drive circuits 21 at the second timing to thereby be able to obtain the change in the rate of operation of the drive circuits 21. Note that a method for dividing a plurality of the blanking devices 22 into blocks is not limited to the method described above. The command generation circuit 36 may also be adapted to capture a change in the operation state by considering the positions of the blanking devices 22 in operation instead of capturing the change in the rate of operation.

Next, a description will be given of calculation of a change (variation) in current flowing through the blanking deflector array 13 in step S101. The current generated when the blanking deflector array 13 is in operation, that is, when a plurality of the drive circuits 21 is in operation, depends on the specification of the blanking deflector array 13. In other words, current can be estimated from, for example, the gate capacitance, junction capacitance, wiring capacitance, and load capacitance of the CMOS circuit and the voltage and frequency of the drive signal applied thereto. Electric current can also be obtained by direct measurement by actually driving the blanking deflector array 13. Then, once the command generation circuit 36 multiplies the current obtained as described above by a change in the rate of operation of the drive circuits 21 obtained from Table 1, the change in current can be calculated. Note that a wiring (not shown) for connecting the drive circuit 21 to the pair of electrodes 20 is also present in the Z-axis direction, and thus, current also flows in the Z-axis direction.

Next, a description will be given of calculation of a change (variation) in magnetic field generated by the blanking deflector array 13 in step S102. For example, the magnetic field variation ΔB due to the variation of current in any one block (specific block) of the first block 50 to the sixth block 55 in the operation state shown in FIGS. 4A and 4B is calculated from the distance between the block and the drive circuits 21 located therearound and is represented by the following Formula 1. Note that a change in magnetic field due to a change in current flowing in the Z-axis direction occurs, for example, in the X-axis direction.

$$Δ B = \frac{μ \times Δ {I}_{n}}{2 \times π \times {R}_{n}} \qquad [ Formula 1 ]$$

Here, μ represents permeability of vacuum, ΔIₙ (n is a number for specifying a block) represents a change (the amount of variation) in current, and Rₙ represents the distance between a specific block and other blocks. The distance can be calculated as a distance between the central points of the blocks. In other words, a change in magnetic field of any one block is the result of integrating the changes in magnetic field generated by the blocks located therearound.

Next, a description will be given of calculation of the amount of shift in step S103. The command generation circuit 36 calculates the amount of deflection of the electron beam due to a change in magnetic field based on the calculation results of the change in magnetic field described above. When the direction of a change in magnetic field is the X-axis direction, the deflected direction of an electron beam due to a change in magnetic field is the Y-axis direction. Then, the command generation circuit 36 calculates the amount of shift (position error) ΔY of the electron beam on the substrate to be treated 7 using the following Formula 2.

ΔY=ΔB×L×2×l [Formula 2]

Here, L represents the distance between the blanking deflector array 13 and the substrate to be treated 7 placed on the substrate stage 5, and l represents the size of the blanking deflector array 13 in the direction of travel to the electron beam (the Z-axis direction). Then, the command generation circuit 36 corrects (changes) the initial drawing pattern based on the amount of shift ΔY in step S104. While, in the present embodiment, the command generation circuit 36 executes the calculation of a change in current or magnetic field based on a change in the rate of operation of the drive circuits 21, the present invention is not limited thereto. For example, the command generation circuit 36 may also measure the amount of shift (position error) of the electron beam in various operation states of the drive circuits 21 using a detector disposed at the upper part of the substrate stage 5 so as to correct the initial drawing pattern based on the results of measurement.

As described above, according to the present embodiment, a drawing apparatus that is advantageous for decreasing the influence of the magnetic field generated by a blanking deflector array may be provided. For executing the processes as described above, the command generation circuit 36 may also include a logic circuit such as a CPU, an FPGA, or an ASIC, and a memory. Also, in the present embodiment, the command generation circuit 36 is included in the control unit 6 and is a component that is separated from the blanking deflector array 13 (the circuit board including the blanking deflector array 13). However, the arrangement of the command generation circuit 36 is not limited thereto. For example, a device (circuit element) for executing a part or all of the functions of the command generation circuit 36 may also be integrated into a circuit board including the blanking deflector array 13.

### (Drawing Data Generation Program)

The present invention may also be realized by executing the following processing. Specifically, a program (software) for realizing the functions of the embodiment is provided in a system or apparatus via network or various storage media. Then, the provided (and stored) program is (read from a storage medium) executed by a computer (a CPU, an MPU, or the like) of the system or apparatus. In this case, the program and the storage medium on which the program is stored constitute the present invention.

### (Article Manufacturing Method)

An article manufacturing method according to an embodiment of the present invention is preferred in, for example, manufacturing a micro device, such as a semiconductor device or the like or an article such as an element or the like having a microstructure. The article manufacturing method may include the step of forming a latent image pattern on a substrate on which a photosensitizing agent is coated using the aforementioned drawing apparatus (a step of drawing a pattern on a substrate); and developing the substrate on which the latent image pattern has been formed in the latent image pattern step. Furthermore, the article manufacturing method may include other known steps (oxidizing, film forming, vapor depositing, doping, flattening, etching, resist peeling, dicing, bonding, packaging, and the like). The article manufacturing method of the present embodiment has an advantage, as compared with a conventional article manufacturing method, in at least one of performance, quality, productivity and production cost of an article.

While the embodiments of the present invention have been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-211863 filed Sep. 28, 2011 which are hereby incorporated by reference herein it their entirety.

What is claimed is:

1. A drawing apparatus that performs drawing on a substrate with a plurality of charged particle beams, the apparatus comprising:
a blanking deflector array including a plurality of blanking deflectors configured to respectively blank the plurality of charged particle beams; and
a controller configured to control the blanking deflector array based on drawing data,
wherein the controller is configured to control the blanking deflector array such that a position error of the plurality of charged particle beams on the substrate due to a magnetic field generated by the blanking deflector array is less than that in a case where the controller controls the blanking deflector array in accordance with initial drawing data.

2. The drawing apparatus according to claim 1, wherein the controller is configured to obtain the position error based on a change in a rate of operation of the plurality of blanking deflectors that operate in accordance with an initial blanking command that is based on the initial drawing data, and to change the initial blanking command so as to reduce the determined position error.

3. The drawing apparatus according to claim 2, wherein the controller is configured to obtain the position error based on a change in the rate of operation with respect to each of blocks into which the plurality of blanking deflectors are divided.

4. The drawing apparatus according to claim 2, wherein the controller is configured to obtain a change in the magnetic field based on the obtained change in the rate of operation, and to obtain the position error based on the obtained change in the magnetic field.

5. A method of generating drawing data for use in a drawing apparatus that performs drawing on a substrate with a plurality of charged particle beams, via a blanking deflector array including a plurality of blanking deflectors configured to respectively blank the plurality of charged particle beams, the method comprising:
generating the drawing data by changing initial drawing data such that a position error of the plurality of charged particle beams on the substrate due to a magnetic field generated by the blanking deflector array is less than that in a case where the blanking deflector array is operated in accordance with the initial drawing data.

6. The method according to claim 5, further comprising:
obtaining a change in a rate of operation of the plurality of blanking deflectors that operate in accordance with the initial drawing data;
obtaining a change in the magnetic field based on the obtained change in the rate of operation;
obtaining the position error based on the obtained change in the magnetic field; and
changing the initial drawing data based on the obtained position error.

7. A storage medium that stores a program for causing a computer to execute a process in a method defined in claim 5.

8. A method of manufacturing an article, the method comprising:
performing drawing on a substrate using a drawing apparatus;
developing the substrate on which the drawing has been performed; and
processing the developed substrate to manufacture the article,
wherein the drawing apparatus performs drawing on the substrate with a plurality of charged particle beams, the apparatus including:
a blanking deflector array including a plurality of blanking deflectors configured to respectively blank the plurality of charged particle beams; and
a controller configured to control the blanking deflector array based on drawing data,
wherein the controller is configured to control the blanking deflector array such that a position error of the plurality of charged particle beams on the substrate due to a magnetic field generated by the blanking deflector array is less than that in a case where the controller controls the blanking deflector array in accordance with initial drawing data.
